(19) United States
(12) Patent Application Publication
(10) Pub. No.: US 2007/0138632 A1
(43) Pub. Date: Jun. 21, 2007

(54) Electronic carrier board and package structure thereof

(75) Inventors: Fang-Lin Tsai, Taichung (TW); Ho-Yi Tsai, Taichung Hsien (TW); Chih-Ming Huang, Hsinchu Hsein (TW); Chien-Ping Huang, Hsinchu Hsein (TW); Cheng-Hsu Hsiao, Taichung Hsien (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/642,439

(22) Filed: Dec. 19, 2006

(30) Foreign Application Priority Data
Dec. 21, 2005 (TW) 094145463

(51) Int. Cl. H01L 23/34

(52) U.S. Cl. 257/724

(57) ABSTRACT

An electronic carrier board and a package structure thereof are provided. The electronic carrier board includes a carrier, at least one pair of bond pads formed on the carrier, and a protective layer covering the carrier. An opening is formed in the protective layer to expose at least three sides of each of the paired bond pads. The protective layer includes at least one independent residual portion located in the opening and between the paired bond pads, such that an electronic component is mounted on the independent residual portion and electrically connected to the bond pads. A groove without a dead space is formed between the electronic component and the carrier, such that a molding compound for encapsulating the electronic component can flow through the groove to fill the opening and a space under the electronic component and encapsulate the at least three sides of each of the bond pads.

### FIELD OF THE INVENTION

The present invention relates to electronic carrier boards and package structures thereof, and more particularly, to an electronic carrier board applicable to surface mounted technology (SMT) and a package structure having the electronic carrier board.

### BACKGROUND OF THE INVENTION

Electronic components have been continuously designed and fabricated to have a miniaturized profile in response to the progress of integrated circuit (IC) manufacturing technology, and with provision of large-scale and highly integrated electronic circuits, IC-based products have relatively complete functionality.

Conventionally, electronic components are mounted on an electronic carrier board (such as a printed circuit board (PCB), a circuit board, or a substrate) by through hole technology (THT). The electronic components used in the THT, as not able to be further reduced in size, are considered occupying a significant amount of space on the electronic carrier board. By the THT, the electronic carrier board needs to have through holes corresponding to pins of the electronic components, such that the electronic components with the pins coupled to the through holes of the electronic carrier board actually occupy space on both sides of the electronic carrier board, and further, solder joints formed at junctions of the electronic components and the electronic carrier board are relatively large. Due to these drawbacks, the THT is no longer used in the mounting process of electronic components, but instead, surface mounted technology (SMT) becomes widely employed nowadays to effectively mount electronic components on an electronic carrier board.

Using the SMT to mount electronic components, electrical connection ends (pins) of the electronic components are bonded to a surface of an electronic carrier board on which the electronic components are mounted, such that there is no need to form plenty of through holes in the electronic carrier board for accommodating the pins of the electronic components as in the case of using the THT. Further by the SMT, the electronic components can be disposed on both sides of the electronic carrier board, thereby greatly improving space utilization of the electronic carrier board. Compared with the electronic components used in the THT, the electronic components used in the SMT have smaller sizes such that more of these electronic components can be mounted on the electronic carrier board by the SMT, and also, the electronic components used in the SMT are more cost-effectively fabricated. These advantages make the SMT become the main technology for mounting electronic components on an electronic carrier board.

The SMT is further advantageous in view of the following aspects. As it becomes necessary to mount passive components (such as capacitors, resistors or inductors) on an electronic carrier board to maintain stable electrical quality of an electronic product, and the electronic product is being made compact in size and with low consumption of power, the THT using relatively large electronic components is not considered suitable and is gradually replaced by the SMT. This is because in the THT, through holes need to be formed in a circuit board to accommodate the pins of the electronic components and are spaced apart from each other by a distance corresponding to a pitch between the pins, and the electronic components with the pins coupled to the through holes occupy both sides of the circuit board, thereby leading to unsatisfactory space utilization of the circuit board. The SMT however does not have such drawbacks.

FIG. 1A is a top view showing passive components mounted on a substrate by the SMT, and FIGS. 1B and 1C are cross-sectional views of FIG. 1A taken along lines 1B-1B and 1C-1C respectively. As shown, a pair of separate bond pads 12 are formed at predetermined positions on a substrate 11, and are exposed through openings 130 of a solder mask layer 13 covering the substrate 11. With an appropriate amount of solder paste 15 being applied on the bond pads 12, end portions of a passive component 14 can be bonded to the solder paste 15 and then subjected to a reflow soldering process, such that the passive component 14 is electrically connected to the bond pads 12 by means of the solder paste 15.

However, it is found difficult to accurately control the height of the passive component 14 bonded to the solder paste 15 due to the amount of the solder paste 15 being used and melting of the solder paste 15 in the reflow soldering process. In case the solder mask layer 13 does not have a flat surface but is usually formed with recesses, a clearance 17 may be generated between the passive component 14 and the solder mask layer 13. The height of the clearance 17 is merely 10 to 30 μm, which is smaller than the size (about 50 μm) of fillers of an epoxy molding compound (EMC) used for encapsulating the passive component 14. As such, in a molding process, the clearance 17 cannot be completely filled with the EMC, and thus voids are formed. The voids result in a popcorn effect in a subsequent high-temperature operating environment, which undesirably damages the whole package structure. Furthermore, the melting solder paste 15 may flow into the clearance 17 (by a capillary action) and lead to undesirable electrical bridging and short circuit of the passive component 14 (as shown in FIG. 1B), thereby adversely affecting the yield of the fabricated package structure.

With a plurality of passive components 14 being provided, the melting solder paste 15 may possibly flow through any gap between the bond pads 12 and the solder mask layer 13 and then through any gap between the substrate 11 and the solder mask layer 13 to form solder extrusion (as indicated by the sign SE in FIG. 1C), which results in short circuit between the adjacent passive components 14.

Another case is shown in FIG. 2, wherein a passive component 24 (such as a 0805-type passive component) is provided, for example, comprising a plurality of paired capacitors or resistors connected in parallel or in series. Correspondingly, a plurality of bond pads for mounting the 0805-type passive component are arranged in pairs, and so are solder mask openings 230 each of which exposes a corresponding one of the bond pads. By such arrangement, it is even more difficult to fill the clearance between the passive component and the substrate with the EMC but easier for the occurrence of the solder extrusion.

Accordingly, U.S. Pat. No. 6,521,997 provides a solution by additionally forming a groove 330 between openings of a solder mask layer 33 where paired bond pads 32 are exposed, as shown in FIG. 3, so as to enlarge the clearance to allow the EMC to pass through the clearance by means of the groove 330.

Altematively, U.S. Published Application No. 2005/0253231 has two grooves 4300 formed between two solder mask openings 430 where paired bond pads 42 are exposed, as shown in FIG. 4A, so as to allow more of the EMC to pass through the clearance by means of the grooves 4300.

However, as shown in FIG. 4B, when an EMC 47 (indicated by arrows) flows into the two grooves 4300 formed between the two solder mask openings 430, space in the grooves 4300 is so small that turbulence of the EMC 47 readily occurs at the comers of the grooves 4300 and thus causes voids V formed in situ, thereby increasing the chance of a popcorn effect in a subsequent thermal processing environment.

Further, neither U.S. Pat. No. 6,521,997 nor U.S. Published Application No. 2005/0253231 as mentioned above is able to effectively solve the problem of short circuit between adjacent passive components due to solder extrusion formed by the solder paste flowing through any gap between the substrate and the solder mask layer.

Therefore, the problem to be solved here is to provide an electronic carrier board and a package structure thereof, which can avoid formation of voids, electrical bridging and solder extrusion in the presence of a clearance formed between the electronic carrier board and an electronic component mounted thereon.

### SUMMARY OF THE INVENTION

In view of the above drawbacks of the prior art, a primary objective of the present invention is to provide an electronic carrier board and a package structure thereof, allowing a space between an electronic component and the electronic carrier board to be effectively filled with an epoxy molding compound (EMC), so as to avoid a void-induced popcorn effect and undesirable electrical bridging.

Another objective of the present invention is to provide an electronic carrier board and a package structure thereof, so as to prevent electrical short circuit between adjacent electronic components.

Still another objective of the present invention is to provide an electronic carrier board and a package structure thereof, allowing a conductive material, which connects an electronic component to the electronic carrier board, to be effectively encapsulated by an EMC, so as to prevent overflow and diffusion of the conductive material.

A further objective of the present invention is to provide an electronic carrier board and a package structure thereof, allowing an EMC encapsulating an electronic component on the electronic carrier board to flow through a groove under the electronic component without the occurrence of voids.

In accordance with the above and other objectives, the present invention proposes an electronic carrier board comprising: a carrier; at least one pair of bond pads formed on a surface of the carrier; and a protective layer covering the surface of the carrier. The protective layer is formed with an opening corresponding to the at least one pair of bond pads to expose at least three sides of each of the paired bond pads. The protective layer includes at least one independent residual portion located in the opening and between the at least one pair of bond pads, such that an electronic component can be mounted on the independent residual portion of the protective layer and electrically connected to the at least one pair of bond pads. By such arrangement, a groove without any dead space is formed between the electronic component and the surface of the carrier, such that an EMC when encapsulating the electronic component can flow through the groove to fill the opening and a space under the electronic component and encapsulate the at least three sides of each of the paired bond pads.

The present invention also proposes a package structure of the electronic carrier board. The package structure comprises: the electronic carrier board, an electronic component, and an EMC. The electronic carrier board comprises: a carrier, at least one pair of bond pads formed on a surface of the carrier, and a protective layer covering the surface of the carrier. The protective layer is formed with an opening corresponding to the at least one pair of bond pads to expose at least three sides of each of the paired bond pads, and the protective layer includes at least one independent residual portion located in the opening and between the at least one pair of bond pads. The electronic component is mounted on the independent residual portion of the protective layer and is electrically connected to the at least one pair of bond pads, with a groove without any dead space being formed between the electronic component and the carrier. The EMC for encapsulating the electronic component may smoothly flow through the groove to fill the opening and a space under the electronic component and encapsulate the at least three sides of each of the paired bond pads. The electronic carrier board can be a substrate, a circuit board, or a printed circuit board, etc. The protective layer can be a solder mask layer. The electronic component can be a passive component.

Therefore, in the electronic carrier board and the package structure thereof according to the present invention, a protective layer covering the electronic carrier board is formed with an opening corresponding to at least one pair of bond pads to expose at least three sides of each of the paired bond pads, and the protective layer includes at least one independent residual portion located in the opening and between the paired bond pads, wherein the independent residual portion is not in contact with the rest of the protective layer. Thus, when an electronic component is mounted on the independent residual portion and is electrically connected to the bond pads via a conductive material as well as is encapsulated by an EMC, the EMC may smoothly flow through the opening under the electronic component to thereby effectively fill the opening and a clearance between the electronic component and the electronic carrier board, such that a void-induced popcorn effect and undesirable electrical bridging are prevented.

Moreover, since at least three sides of each of the paired bond pads are exposed through the opening of the protective layer, when the EMC effectively fills the opening and the clearance between the electronic component and the electronic carrier board, it also encapsulates the at least three sides of each of the paired bond pads. This thus solves the problem of short circuit between adjacent passive components due to solder extrusion caused by solder paste flowing through any gap between a bond pad and a solder mask layer and then through any gap between a substrate and the solder mask layer in the prior art.

Further in the present invention, since the protective layer has at least one independent residual portion located in the opening and between the paired bond pads and being not in contact with the rest of the protective layer, when the electronic component is mounted on the independent residual portion and is electrically connected to the bond pads via the conductive material as well as is encapsulated by the EMC, a groove without any dead space is provided between the electronic component and the electronic carrier board to allow the EMC to smoothly flow through the groove and fill the clearance between the electronic component and the electronic carrier board. This arrangement prevents the occurrence of turbulence of the EMC and thus solves the problem of voids and a popcorn effect caused by turbulence of the EMC occurring at corners of a small groove under an electronic component.

### BRIEF DESCRIPTION OF THE DRAWINGS

The present invention can be more fully understood by reading the following detailed description of the preferred embodiments, with reference made to the accompanying drawings, wherein:

FIG. 1A (PRIOR ART) is a top view showing passive components mounted on a substrate by surface mounted technology (SMT) conventionally;

FIGS. 1B and 1C (PRIOR ART) are cross-sectional views of FIG. 1A taken along lines 1B-1B and 1C-1C respectively;

FIG. 2 (PRIOR ART) is a top view of a passive component mounted on a substrate conventionally;

FIG. 3 (PRIOR ART) is a cross-sectional view of a package including a passive component as disclosed in U.S. Pat. No. 6,521,997;

FIGS. 4A and 4B (PRIOR ART) are schematic diagrams showing a substrate and distribution of an EMC as disclosed in U.S. Published Application No. 2005/0253231;

FIGS. 5A and 5B are top views of an electronic carrier board and an electronic component mounted thereon according to a first preferred embodiment of the present invention;

FIG. 6 is a schematic diagram showing an EMC flowing under an electronic component according to the present invention;

FIG. 7 is a top view of an electronic carrier board according to a second preferred embodiment of the present invention;

FIG. 8 is a top view of an electronic carrier board according to a third preferred embodiment of the present invention;

FIG. 9 is a top view of an electronic carrier board according to a fourth preferred embodiment of the present invention; and

FIG. 10 is a top view of an electronic carrier board according to a fifth preferred embodiment of the present invention.

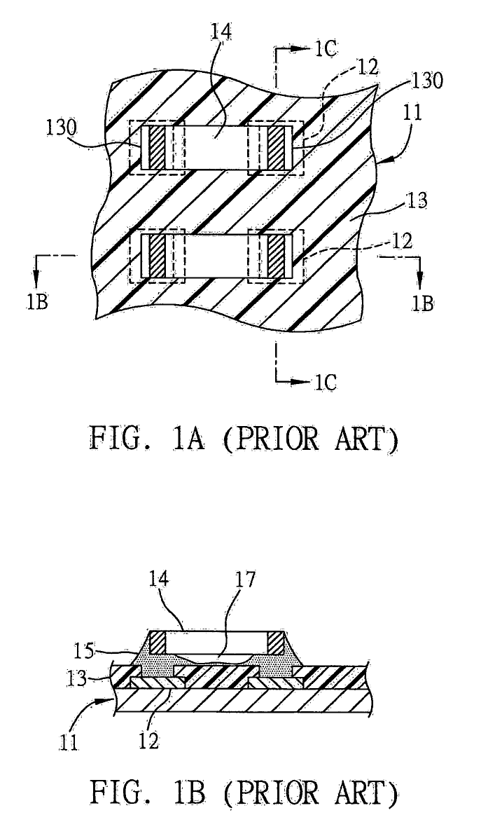

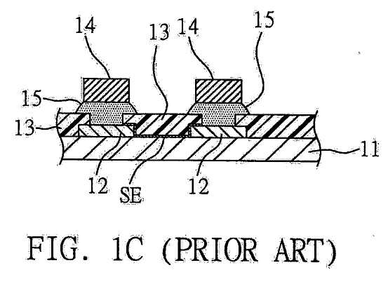

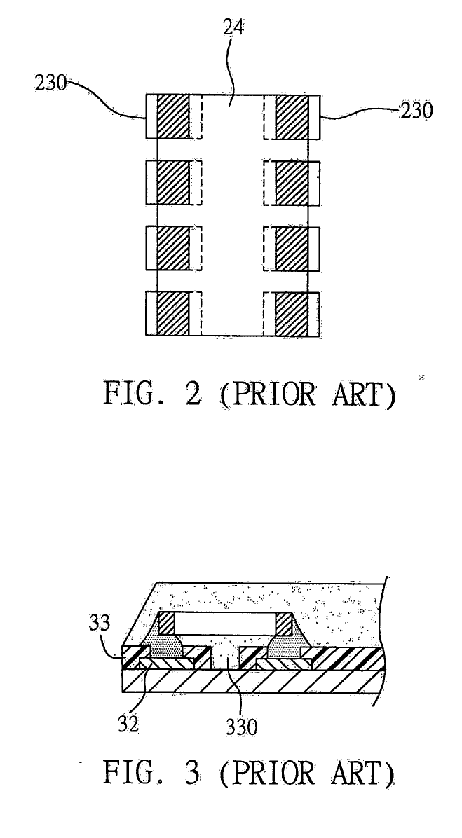

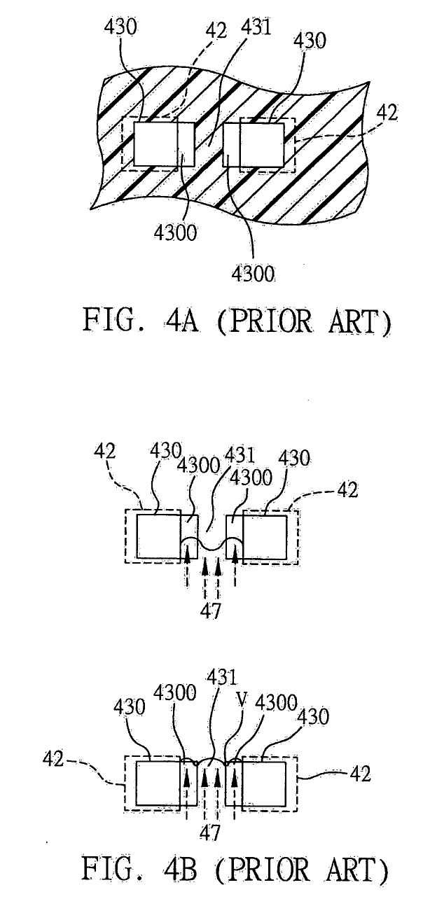

### DETAILED DESCRIPTION OF THE PREFERRED EMBODIMENTS

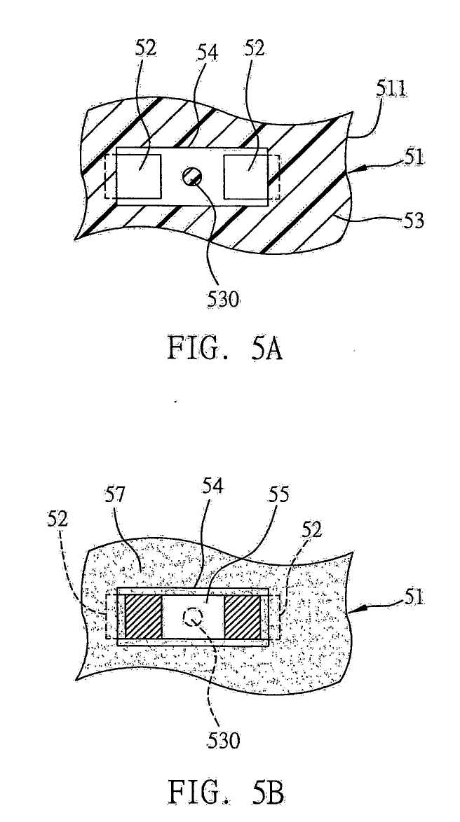

Preferred embodiments of an electronic carrier board and a package structure thereof proposed in the present invention are described as follows with reference to FIGS. 5 to 10. It should be understood that the drawings are simplified schematic diagrams only showing the elements relevant to the present invention, and the layout of elements could be more complicated in practical implementation.

### First Preferred Embodiment

FIGS. 5A and 5B are top views of an electronic carrier board and an electronic component mounted thereon according to a first preferred embodiment of the present invention.

Referring to FIGS. 5A and 5B, the electronic carrier board 51 of the present invention comprises: a carrier 511; a plurality of bond pads, including at least one pair of bond pads 52, formed on a surface of the carrier 511; and a protective layer 53 covering the surface of the carrier 511. The protective layer 53 is formed with an opening 54 corresponding to the at least one pair of bond pads 52 to expose at least three sides of each of the paired bond pads 52. And the protective layer 53 includes at least one independent residual portion 530 located in the opening 54 and between the paired bond pads 52.

The electronic carrier board 51 can be a package substrate used for chip packaging, a circuit board, or a printed circuit board, etc. In this embodiment, the package substrate is described. The carrier 511 of the electronic carrier board 51 can be an insulating layer or an insulating layer with circuit layers stacked therein. A plurality of conductive traces (not shown) and the bond pads 52 are disposed on the surface of the carrier 511. The insulating layer can be made of glass fiber, epoxy resin, polyimide tape, FR4 resin, or bismaleimide triazine (BT) resin, etc., and the circuit layers comprise copper layers.

The carrier 511 of the electronic carrier board 51 is covered with the protective layer 53 such as a solder mask layer made of a polymer with high fluidity (e.g. epoxy resin). The opening 54 of the protective layer 53 is formed at a position corresponding to the at least one pair of bond pads 52 to expose the at least three sides of each of the paired bond pads 52. The protective layer 53 also includes the at least one independent residual portion 530 located in the opening 54 and between the paired bond pads 52, wherein the independent residual portion 530 is not in contact with the rest of the protective layer 53.

The present invention also proposes a package structure of the electronic carrier board. The package structure comprises the electronic carrier board 51, an electronic component 55, and a molding compound such as an epoxy molding compound (EMC) 57. The electronic carrier board 51 comprises the carrier 511, the at least one pair of bond pads 52 formed on the carrier 511, and the protective layer 53 covering the carrier 511, wherein the protective layer 53 is formed with the opening 54 corresponding to the at least one pair of bond pads 52 to expose the at least three sides of each of the paired bond pads 52, and the protective layer 53 includes the at least one independent residual portion 530 located in the opening 54 and between the paired bond pads 52. The electronic component 55 is mounted on the independent residual portion 530 of the protective layer 53 and is electrically connected to the paired bond pads 52, wherein a groove without a dead space is formed between the electronic component 55 and the carrier 511. The EMC 57 encapsulates the electronic component 55, fills the opening 54 and a space under the electronic component 55, and thereby encapsulates the at least three sides of each of the paired bond pads 52.

The electronic component 55 can be mounted on and well supported by the independent residual portion 530 of the protective layer 53. A conductive material such as solder paste (not shown) is used to electrically connect two end portions of the electronic component 55 to the paired bond pads 52 exposed from the protective layer 53, and then a reflow soldering process is performed, such that the electronic component 55 is bonded to and electrically coupled to the bond pads 52 by means of the solder paste. The electronic component 55 can be a passive component.

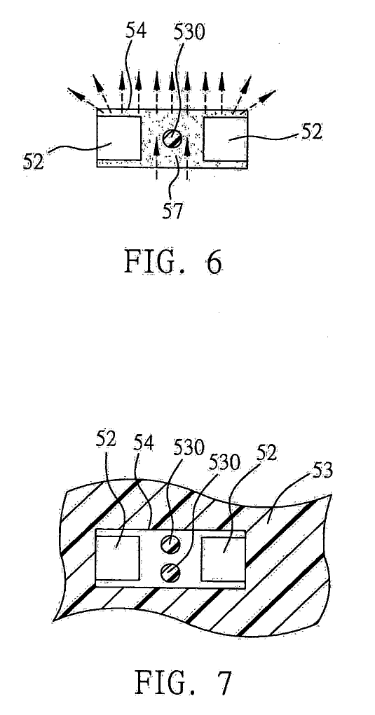

FIG. 6 is a schematic diagram showing the EMC flowing under the electronic component according to the present invention. As shown in FIGS. 5B and 6, the protective layer 53 is formed with the single opening 54 corresponding to the at least one pair of bond pads 52 to expose the at least three sides of each of the paired bond pads 52, and the protective layer 53 includes the at least one independent residual portion 530 located in the opening 54 and between the paired bond pads 52, wherein the independent residual portion 530 is not in contact with the rest of the protective layer 53. By such arrangement, the groove without the dead space is formed between the electronic component 55 and the carrier 511 for the EMC 57 to flow through the groove (indicated by arrows) such that the EMC 57 can smoothly flow under the electronic component 55 to effectively fill the opening 54 and a clearance between the electronic component 55 and the electronic carrier board 51. With the clearance between the electronic component 55 and the electronic carrier board 51 being filled with the EMC 57, it avoids voids being formed in the clearance and thus prevents a popcorn effect in a subsequent thermal environment, as well as provides an electrical insulation barrier between the paired bond pads to prevent undesirable electrical bridging between the paired bond pads.

Moreover, since the at least three sides of each of the paired bond pads 52 are exposed through the opening 54, the EMC 57 encapsulates the at least three sides of each of the paired bond pads 52. This thus solves the problem of short circuit between adjacent passive components due to solder extrusion caused by solder paste flowing through any gap between a bond pad and a solder mask layer and then through any gap between a substrate and the solder mask layer in the prior art.

### Second Preferred Embodiment

FIG. 7 is a top view of an electronic carrier board according to a second preferred embodiment of the present invention.

The electronic carrier board and a package structure thereof of this second embodiment are similar to those of the first preferred embodiment, with a primary difference in that, in the second embodiment, the protective layer 53 includes a plurality of independent residual portions 530 located in the opening 54 and between the at least one pair of bond pads 52. Two independent residual portions are shown in FIG. 7 but do not set a limitation for the present invention. These independent residual portions 530 are not in contact with the rest of the protective layer 53. By such arrangement, the electronic component can be well supported by the independent residual portions 530 and the EMC 57 can smoothly flow through the groove without the dead space under the electronic component and fill the space under the electronic component.

### Third Preferred Embodiment

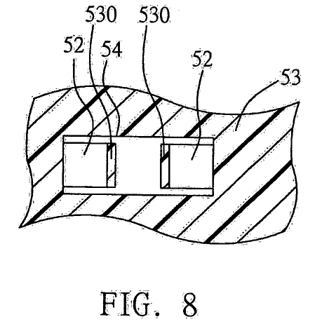

FIG. 8 is a top view of an electronic carrier board according to a third preferred embodiment of the present invention.

The electronic carrier board and a package structure thereof of this third embodiment are similar to those of the first preferred embodiment, with a primary difference in that, in the third embodiment, the protective layer 53 includes a plurality of independent residual portions 530 located in the opening 54 and between the at least one pair of bond pads 52. Two independent residual portions are shown in FIG. 7 but do not set a limitation for the present invention. These independent residual portions 530 come into contact with the bond pads 52 but are not in contact with the rest of the protective layer 53. By such arrangement, the electronic component can be well supported by the independent residual portions 530 and the EMC 57 can smoothly flow through the groove without the dead space under the electronic component and fill the space under the electronic component.

### Fourth Preferred Embodiment

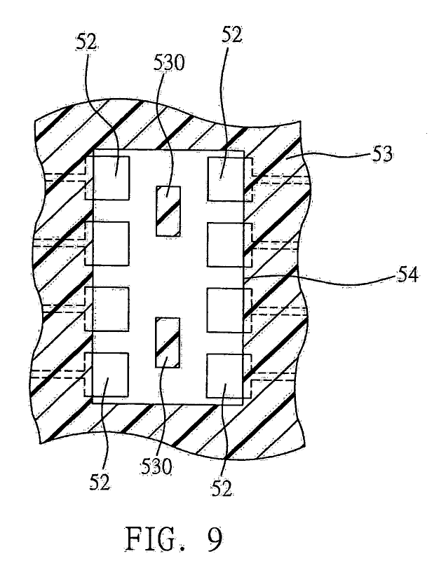

FIG. 9 is a top view of an electronic carrier board according to a fourth preferred embodiment of the present invention.

The electronic carrier board and a package structure thereof of this fourth embodiment are similar to those of the first preferred embodiment, with a primary difference in that, in the fourth embodiment, a plurality of pairs of bond pads 52 are formed on the electronic carrier board, and the protective layer 53 covering the electronic carrier board is formed with a single opening 54 corresponding to the plurality of pairs of bond pads 52 to simultaneously expose at least three sides of each of the bond pads 52. Thus, in a subsequent process, a passive component comprising component units connected in parallel or in series, such as a 0805-type passive component, can be mounted on and electrically connected to the plurality of pairs of bond pads 52.

In this embodiment, by the arrangement having the single opening 54 of the protective layer 53 formed at a position corresponding to all the plurality of pairs of bond pads 52 to expose the at least three sides of each of the bond pads 52, the drawback in the prior art such as difficulty in filling a space under a passive component (e.g. a 0805-type passive component) with an EMC can be overcome, and the EMC in this embodiment can encapsulate each of the bond pads, thereby reducing the occurrence of solder extrusion.

Moreover, in this embodiment, the protective layer 53 includes a plurality of independent residual portions 530, which have for example a rectangular shape and are located in the opening 54 and between the paired bond pads 52, so as to effectively support a large passive component such as the 0805-type passive component.

### Fifth Preferred Embodiment

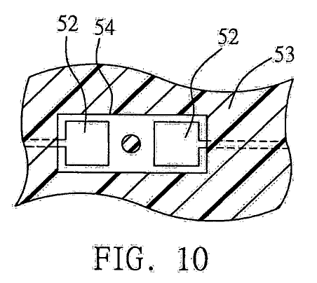

FIG. 10 is a top view of an electronic carrier board according to a fifth preferred embodiment of the present invention.

The electronic carrier board and a package structure thereof of this fifth embodiment are similar to those of the first preferred embodiment, with a primary difference in that, in the fifth embodiment, the opening 54 of the protective layer 53, corresponding to the at least one pair of bond pads 52, exposes four sides of each of the paired bond pads 52, such that the bond pads 52 are completely exposed through the opening 54.

Accordingly, in a subsequent process, the EMC completely encapsulates the bond pads. This solves the problem of short circuit between adjacent passive components due to solder extrusion caused by solder paste flowing through any gap between a bond pad and a solder mask layer and then through any gap between a substrate and the solder mask layer in the prior art.

Therefore, in the electronic carrier board and the package structure thereof according to the present invention, a protective layer covering the electronic carrier board is formed with an opening corresponding to at least one pair of bond pads to expose at least three sides of each of the paired bond pads, and the protective layer includes at least one independent residual portion located in the opening and between the paired bond pads, wherein the independent residual portion is not in contact with the rest of the protective layer. Thus, when an electronic component is mounted on the independent residual portion and is electrically connected to the bond pads via a conductive material as well as is encapsulated by an EMC, the EMC may smoothly flow through the opening under the electronic component to thereby effectively fill the opening and a clearance between the electronic component and the electronic carrier board, such that a void-induced popcorn effect and undesirable electrical bridging are prevented.

Moreover, since at least three sides of each of the paired bond pads are exposed through the opening of the protective layer, when the EMC effectively fills the opening and the clearance between the electronic component and the electronic carrier board, it also encapsulates the at least three sides of each of the paired bond pads. This thus solves the problem of short circuit between adjacent passive components due to solder extrusion caused by solder paste flowing through any gap between a bond pad and a solder mask layer and then through any gap between a substrate and the solder mask layer in the prior art.

Further in the present invention, since the protective layer has at least one independent residual portion located in the opening and between the paired bond pads and being not in contact with the rest of the protective layer, when the electronic component is mounted on the independent residual portion and is electrically connected to the bond pads via the conductive material as well as is encapsulated by the EMC, a groove without any dead space is provided between the electronic component and the electronic carrier board to allow the EMC to smoothly flow through the groove and fill the clearance between the electronic component and the electronic carrier board. This arrangement prevents the occurrence of turbulence of the EMC and thus solves the problem of voids and a popcorn effect caused by turbulence of the EMC occurring at corners of a small groove under an electronic component.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. An electronic carrier board comprising:
a carrier;
at least one pair of bond pads formed on a surface of the carrier; and
a protective layer covering the surface of the carrier, the protective layer being formed with an opening corresponding to the at least one pair of bond pads to expose at least three sides of each of the at least one pair of bond pads, and the protective layer including at least one independent residual portion located in the opening and between the at least one pair of bond pads, allowing an electronic component to be mounted on the independent residual portion and electrically connected to the at least one pair of bond pads, with a groove free of a dead space being formed between the electronic component and the surface of the carrier, so as to allow a molding compound for encapsulating the electronic component to flow through the groove to fill the opening and a space under the electronic component and encapsulate the at least three surfaces of each of the at least one pair of bond pads.

2. The electronic carrier board of claim 1, wherein the electronic carrier board is one of a package substrate, a circuit board, and a printed circuit board.

3. The electronic carrier board of claim 1, wherein the carrier is one of an insulating layer and an insulating layer with circuit layers stacked therein.

4. The electronic carrier board of claim 1, wherein the protective layer is a solder mask layer made of a polymer with high fluidity.

5. The electronic carrier board of claim 1, wherein the independent residual portion is free of being in contact with the rest of the protective layer.

6. The electronic carrier board of claim 1, wherein the independent residual portion is in contact with at least one of the bond pads.

7. The electronic carrier board of claim 1, wherein the at least one pair of bond pads comprise a plurality of pairs of bond pads, and the opening of the protective layer corresponds to the plurality of pairs of bond pads to expose the plurality of pairs of bond pads for being electrically connected with a passive component comprising component units connected in series or in parallel.

8. The electronic carrier board of claim 1, which allows solder paste to be applied on the bond pads, such that the electronic component is electrically connected to the bond pads by the solder paste.

9. The electronic carrier board of claim 1, wherein the opening exposes four sides of each of the at least one pair of bond pads, such that the bond pads are completely exposed.

10. The electronic carrier board of claim 1, wherein the electronic component comprises a passive component.

11. A package structure of an electronic carrier board, comprising:
the electronic carrier board comprising a carrier, at least one pair of bond pads formed on a surface of the carrier, and a protective layer covering the surface of the carrier, wherein the protective layer is formed with an opening corresponding to the at least one pair of bond pads to expose at least three sides of each of the at least one pair of bond pads, and the protective layer includes at least one independent residual portion located in the opening and between the at least one pair of bond pads;
an electronic component mounted on the independent residual portion of the protective layer and electrically connected to the at least one pair of bond pads, wherein a groove free of a dead space is formed between the electronic component and the surface of the carrier; and
a molding compound encapsulating the electronic component, filling the opening and a space under the electronic component, and encapsulating the at least three sides of each of the at least one pair of bond pads.

12. The package structure of claim 11, wherein the electronic carrier board is one of a package substrate, a circuit board, and a printed circuit board.

13. The package structure of claim 11, wherein the carrier is one of an insulating layer and an insulating layer with circuit layers stacked therein.

14. The package structure of claim 11, wherein the protective layer is a solder mask layer made of a polymer with high fluidity.

15. The package structure of claim 11, wherein the independent residual portion is free of being in contact with the rest of the protective layer.

16. The package structure of claim 11, wherein the independent residual portion is in contact with at least one of the bond pads.

17. The package structure of claim 11, wherein the at least one pair of bond pads comprise a plurality of pairs of bond pads, and the opening of the protective layer correspond to the plurality of pairs of bond pads to expose the plurality of pairs of bond pads for being electrically connected with a passive component comprising component units connected in series or in parallel.

18. The package structure of claim 11, further comprising solder paste applied on the bond pads, such that the electronic component is electrically connected to the bond pads by the solder paste.

19. The package structure of claim 11, wherein the opening exposes four sides of each of the at least one pair of bond pads, such that the bond pads are completely exposed.

20. The package structure of claim 11, wherein the electronic component comprises a passive component.
